(19) United States
(12) Patent Application Publication
(10) Pub. No.: US 2025/0341547 A1
(43) Pub. Date: Nov. 6, 2025

(54) RESIDUAL CURRENT OPERATED DEVICE WITH ALL-CURRENT SENSITIVE DETECTION OF DIFFERENTIAL CURRENTS AND CHARGING PLUG, IN-CABLE CONTROL BOX, CHARGING CABLE AND CHARGER THEREWITH

(71) Applicant: Magnetec GmbH, Hanau (DE)

(72) Inventor: David TOTH, Rodenbach (DE)

(21) Appl. No.: 18/871,027

(22) PCT Filed: Apr. 21, 2023
(86) PCT No.: PCT/EP2023/060477

§ 371 Date: Dec. 2, 2024

(30) Foreign Application Priority Data
May 30, 2022 (DE) 10 2022 113 560.8

(51) Int. Cl. G01R 15/18; B60L 53/16; B60L 53/18; B60L 53/62; G01R 19/00

(52) U.S. Cl. CPC G01R 15/18; B60L 53/16; B60L 53/18; B60L 53/62; G01R 19/0092

(57) ABSTRACT

A residual current device is configured for connection to a power supply network having at least two power supply conductors and includes a switching device for interrupting the at least two power supply conductors, a sensor for detecting residual currents in the at least two power supply conductors, and a control circuit which is designed to detect a residual current between the at least two power supply conductors using the sensor and, when a residual current is detected, to control the switching device to carry out a switching operation.

The present invention relates to a residual current device for connection in a power supply network having at least two power supply conductors, comprising
a switching device, in particular in the form of a disconnector for interrupting the at least two power supply conductors,
a sensor for detecting residual currents in the at least two power supply conductors, and
a control circuit which is designed to detect a residual current between the at least two power supply conductors using the sensor and, when a residual current is detected, to control the switching device to carry out a switching operation.

The present invention also relates to a charging plug for connecting at least two power supply conductors to a charging connection, in particular for connection to a charging connection of an electrically drivable vehicle.

The present invention also relates to a connecting plug for connecting at least two power supply conductors to a grid connection of a power supply network, in particular for connecting a charging cable for an electrically drivable vehicle to the grid connection of the power supply network.

The present invention also relates to an in-cable monitoring box for insertion into an electrical line having at least two power supply conductors, in particular into a charging cable for connecting a charging connection of an electrically drivable vehicle to a grid connection of a power supply network.

The present invention also relates to a charging cable having a charging plug for connection to a charging connection of an electrically drivable vehicle and a connecting plug for connection to a grid connection of a power supply network, wherein
the charging plug and the connecting plug are connected to one another via an electrical line having at least two power supply conductors.

The present invention also relates to a charging cable having a charging plug for connection to a charging connection of an electrically drivable vehicle and a connecting plug for connection to a grid connection of a power supply network, wherein
the charging plug and the connecting plug are connected to each other via an electrical line having at least two power supply conductors.

The present invention also relates to a charging cable having a charging plug for connection to a charging connection of an electrically drivable vehicle and a connecting plug for connection to a grid connection of a power supply network, wherein
the charging plug and the connecting plug are connected to one another via an electrical line having at least two power supply conductors, and
the charging cable comprises an in-cable monitoring box that is integrated into the electrical line.

The present invention also relates to a charging device for charging an energy storage device of an electrically drivable vehicle via at least two power supply conductors of a power supply network.

Residual current sensors are available in a variety of designs for different applications, as residual currents can be a hazard to people and can cause fires.

Residual currents can occur when a defect is present in an electrical power supply network, in particular in a circuit within an electrical power supply network, causing a residual current to flow to earth within the electrical power supply network. The outgoing current cannot directly be detected. Therefore, the power supply conductors must be monitored to detect a difference between the currents in the power supply conductors. Depending on the type and structure of the electrical power supply network, residual currents may comprise alternating current components and/or direct current components. In practice, there is an increasing prevalence of electrical systems in which AC and DC power supply networks are coupled to one another, particularly in the field of electromobility. For instance, batteries of electric vehicles are charged with direct current. In particular in the domestic sector, alternating current is typically provided for charging, which must be converted into direct current. There are also many charging stations where alternating current is provided for charging. A DC power supply network is therefore connected downstream of an AC power supply network. As a result, the DC components of residual currents are becoming increasingly important, even in AC power supply networks.

It is typical, particularly in the case of electrical house installations, for only type A residual current devices (FI circuit breakers) to be installed, which can monitor the in-house electrical AC power supply network for residual currents with AC components. However, type A residual current devices are not suitable for detecting DC faults and shutting down in the event of a defect.

Therefore, in particular when operating charging infrastructure or similar downstream from such an AC power supply network, an all-current sensitive monitoring of residual currents is necessary, which includes a sensor whose measured value, when a limit value is exceeded, leads to the infrastructure concerned being switched off.

Type B residual current devices are therefore known for the downstream operation of charging infrastructure or the like via AC power supply networks, which can also detect and monitor DC components of residual currents. However, type B residual current devices are particularly cost-intensive and for this reason have not been widely used to this point.

An all-current sensitive residual current device simultaneously monitors all currents flowing in the phases and the neutral conductor with its sensor and detects possible DC and AC defects. Depending on the application, the residual current device can automatically shut down the system in the event of a malfunction or report an excess of the switching threshold to a superordinate control unit. Since the tolerable residual currents are minute, outstanding measurement accuracy is necessary. In addition, personal safety requires particularly fast detection and subsequent shutdown of the power supply network.

In order to ensure an accurate measurement of residual current, e.g. in car charging cables, wall boxes (household), charging columns (public) or in the vehicle itself, which also reliably detects a DC current error, Royer oscillators are often used. In this concept, the magnetic core is driven into saturation, causing the conduction phase of a transistor to change and the magnetic core to be saturated in the other direction.

However, the available applications are often large and costly, and it is therefore often not possible to detect DC faults, or a separate system is provided for this purpose.

The present invention addresses the objective of providing a residual current device, a charging plug, an in-cable monitoring box, a charging cable and a charging device of the above-mentioned type that at least partially solves the aforementioned problems. A further objective of the present invention is to provide a residual current device, a charging plug, an in-cable monitoring box, a charging cable and a charging device of the above-mentioned type that allows for simple and safe operation of a power supply network with a DC power supply network connected to it, and in particular that allows for simple, efficient and safe charging of electrical energy storage devices of electrically drivable vehicles.

The objective underlying the present invention is achieved by a residual current device comprising the features of claim 1. Preferred embodiments of the residual current device are described in claims 2 to 11, dependent on claim 1.

In more detail, the underlying objective of the present invention is achieved by a residual current device for connection in a power supply network having at least two power supply conductors, comprising
a switching device, in particular in the form of a disconnector for interrupting the at least two power supply conductors,
a sensor for detecting residual currents in the at least two power supply conductors, and
a control circuit which is designed to detect a residual current between the at least two power supply conductors using the sensor and, when a residual current is detected, to control the switching device to carry out a switching operation.

The residual current device according to the invention is characterized in that
the sensor comprises a magnetic-field-sensitive component having a clearance through which the at least two power supply conductors are routed, and at least one excitation and sensor winding which, with a plurality of turns, encloses the magnetic-field-sensitive component,
the magnetic-field-sensitive component is made of a soft magnetic material,
the control circuit is designed to control the sensor and to detect AC and/or DC components of the residual current in the at least two power supply conductors via the at least one excitation and sensor winding, and
the switching device, the sensor and the control circuit are designed integrally.

The objective underlying the present invention is additionally achieved by a charging plug with the features of claim 12.

In more detail, the underlying task of the present invention is solved by a charging plug for connecting at least two power supply conductors to a charging connection, in particular for connection to a charging connection of an electrically drivable vehicle.

The charging plug according to the invention is characterized in that
the charging plug comprises a residual current device as described above.

The objective underlying the present invention is additionally achieved by a connecting plug with the features of claim 13.

In more detail, the underlying task of the present invention is solved by a connecting plug for connecting at least two power supply conductors to a grid connection of a power supply network, in particular for connecting a charging cable for an electrically drivable vehicle to the grid connection of the power supply network.

The connecting plug according to the invention is characterized in that
the connecting plug comprises a residual current device as described above.

The objective underlying the present invention is also achieved by an in-cable monitoring box with the features of claim 14.

In more detail, the underlying task of the present invention is solved by an in-cable monitoring box for insertion into an electrical line having at least two power supply conductors, in particular into a charging cable for connecting a charging connection of an electrically drivable vehicle to a grid connection of a power supply network.

The in-cable monitoring box according to the invention is characterized in that
the in-cable monitoring box comprises a residual current device as described above.

The objective underlying the present invention is also achieved by charging cable with the features of claim 15.

In more detail, the underlying task of the present invention is solved by a charging cable having a charging plug for connection to a charging connection of an electrically drivable vehicle and a connecting plug for connection to a grid connection of a power supply network, wherein
the charging plug and the connecting plug are connected to one another via an electrical line having at least two power supply conductors.

The charging cable according to the invention is characterized in that
the charging plug is configured as the charging plug above.

The objective underlying the present invention is also achieved by charging cable with the features of claim 16.

In more detail, the underlying task of the present invention is solved by a charging cable having a charging plug for connection to a charging connection of an electrically drivable vehicle and a connecting plug for connection to a grid connection of a power supply network, wherein
the charging plug and the connecting plug are connected to each other via an electrical line having at least two power supply conductors.

The charging cable according to the invention is characterized in that
the charging plug is configured as the charging plug above.

The objective underlying the present invention is also achieved by charging cable with the features of claim 17.

In more detail, the underlying task of the present invention is solved by a charging cable having a charging plug for connection to a charging connection of an electrically drivable vehicle and a connecting plug for connection to a grid connection of a power supply network, wherein
the charging plug and the connecting plug are connected to one another via an electrical line having at least two power supply conductors, and
the charging cable comprises an in-cable monitoring box that is integrated into the electrical line.

The charging cable according to the invention is characterized in that
the in-cable monitoring box is configured as the above in-cable monitoring box.

The objective underlying the present invention is also achieved by a charging device with the features of claim 18.

In more detail, the underlying task of the present invention is solved by a charging device for charging an energy storage device of an electrically drivable vehicle via at least two power supply conductors of a power supply network.

The charging device according to the invention is characterized in that
the charging device comprises an above-mentioned residual current device.

The idea underlying the present invention is the provision of a compact residual current device combining the switching device, the sensor and the control circuit, which makes the residual current device simple to use. This in turn allows for a simplification of the integration of the residual current device into different components like the charging plugs, in-cable monitoring boxes, charging cables and charging devices referred to here. In particular, the provision of the charging plugs, in-cable monitoring boxes, charging cables and charging devices referred to here allows for the connection of power supply networks of electrically drivable vehicles. The provision of the compact residual current device is based on the use of the magnetic-field-sensitive component for the sensor. The power supply conductors can be routed through the magnetic-field-sensitive component, and by controlling it via the at least one excitation and sensor winding, the magnetic-field-sensitive component can be transferred to desired states in which a sensor signal can be picked up via the at least one excitation and sensor winding, enabling a reliable determination of the residual current with AC components as well as DC components. The control circuit can determine these components of the residual current with a high degree of accuracy and control the switching device accordingly to interrupt the power supply through the power supply network when a residual current occurs. In this case, the supply is also automatically interrupted in a downstream DC power supply network and a safe state is assumed. The integral provision of the residual current device enables it to be designed in a particularly compact way.

For example, the residual current device can be designed with a printed circuit board on which the switching device, the sensor and the control circuit are arranged. The magnetic-field-sensitive component is arranged so that the supply conductors can be routed through the clearance. The switching device can also be arranged accordingly and inserted into the supply conductors so that the switching device can interrupt a current flow through the supply conductors. The printed circuit board can thus be provided in a simple and cost-effective manner, since it does not constitute part of the power supply line and does not have to carry any power supply currents. The printed circuit board can contact the power supply conductors in order to obtain energy for its operation via these conductors. In summary, this design enables a simple realization of an integral design of the residual current device.

In terms of function and contacts, the charging plug is a pre-defined charging plug. In Germany, currently common charging plugs include, by way of example, type 1, type 2, CCS, CHAdeMO and Tesla's Supercharger, although the charging plugs are not limited to the examples given. The type 2 plug is alternatively known as the Mennekes plug, while the CCS plug is also known as the Combo plug. The charging plugs do not usually have any further function beyond establishing the electrical connection with the electrically driveable vehicle. Through the provision of the residual current device, integration into the charging plug can be carried out so that, for example, a separate in-cable monitoring box that is introduced into the electrical line with the power supply conductors can be dispensed with. This facilitates the handling of charging cables when charging electrically driveable vehicles. The charging plug is part of a permanently installed charging infrastructure or a portable charging cable that has the charging plug on one side and the connecting plug for connecting to the grid connection of the power supply network on the other.

The in-cable monitoring box (also known as an in-cable control box, or ICCB, or an in-cable control and protection device, or ICCPD) is a device that is permanently integrated into the electrical lines of a charging cable for controlling the charging of electric vehicles, for example, at standard household sockets. The device takes over safety and communication functions when charging at these household sockets to avoid overloading them. This enables charging according to “Mode 2” to be achieved in accordance with IEC 61851-1. Without the in-cable monitoring box, only “Mode 1” can be achieved.

The charging cable connects the charging connection of the electrically drivable vehicle to the grid connection of the power supply network. The grid connection of the power supply network is, for example, a corresponding household socket. Accordingly, the charging cable is designed with the charging plug on the side of the electrically drivable vehicle and with a corresponding connecting plug on the side of the grid connection. The charging cable can thus be used independently and can, for example, be carried in a vehicle. The residual current device, which is located either in an in-cable monitoring box or the charging plug, allows the charging cable to be provided in a compact form. As a result, the charging cable is easier to transport, especially when carried in the vehicle itself.

The charging device is usually installed permanently. These charging devices, for example as wall-mounted charging stations, are also known as “wallboxes”. The charging device enables charging according to “Mode 3” in accordance with IEC 61851-1. An electrical line with at least two power supply conductors is usually permanently connected to the charging device. A charging plug is attached to the free end of the electrical line for connecting to the electrically drivable vehicle. Since the residual current device is already integrated into the charging device, no in-cable monitoring box is required along the electrical line. Furthermore, the charging plug does not require a residual current device.

The power supply network typically supplies alternating current. Such supplies can be provided, for example, in the household sector with two power supply conductors. A single-phase supply with a phase and a neural conductor is provided, whereby an additional ground conductor can be routed in parallel with the power supply conductors as a protective conductor. Alternatively, supplies with three power supply conductors are known.

A three-phase supply is provided, also known as three-phase current, which typically includes an additional neural conductor. Again, other conductors, such as protective conductors as ground conductors and/or PE (protected earth), can be routed in parallel to the power supply conductors.

The switching device is usually configured as a relay or as a contactor. The switching device thus includes a mechanical switch and an electromechanical drive, usually with a drive coil, for operating the mechanical switch. Alternatively, the switching device can be configured with semiconductor switching elements, for example with transistors or others.

The “sensor” is a technical assembly that can qualitatively or quantitatively as a “measured variable” determine certain physical or chemical properties and/or the material composition of its environment. These variables are determined by means of physical or chemical effects and converted into an analog or digital electrical signal. Such a signal is also referred to as a “sensor signal”. The sensor signal is provided here by the at least one excitation and sensor winding. Here, the sensor is used to detect electrical and/or magnetic fields.

Preferably, the sensor signal can be converted into a residual current of the power supply conductors monitored by the sensor by means of a mathematical function. Preferably, this mathematical function can be determined by a calibration curve of the sensor.

An “electrical residual current” is defined as the vectorial sum of the currents of all electrical conductors that pass through the clearance of the magnetic-field-sensitive component. The electrical residual current may comprise an alternating current component and/or a direct current component, which can be determined using the sensor. This means that the residual current device can be designed to be all-current sensitive.

A “magnetic-field-sensitive component” is a component that reacts to a magnetic field by changing at least one of its state variables. The magnetic-field-sensitive component is made of a soft magnetic material and has magnetic properties.

A “soft magnetic material” is a material that can be easily magnetized in a magnetic field. Preferably, a soft magnetic material has a coercive field strength of less than 1,000 A/m.

“Coercive field strength” refers to the magnetic field strength necessary to completely demagnetize a magnetic-field-sensitive component that has previously been charged to the saturation flux density.

“Winding” refers to a winding of an electrically conductive material, in particular in the form of a wire, around a magnetic-field-sensitive component.

At least one “excitation and sensor winding” describes a winding that is designed to be actively supplied with an electric current by means of a current source. Alternatively, the at least one excitation and sensor winding can also be connected to a voltage source. An electromagnetic field is generated or influenced in the magnetic-field-sensitive component via the at least one excitation and sensor winding.

Preferably, the at least one excitation and sensor winding is designed to provide a sensor signal, in particular indirectly through the current consumption of the at least one excitation and sensor winding.

Preferably, the residual current of the circuit monitored by the sensor can be determined from the current consumption of the at least one excitation and sensor winding by means of a mathematical function, preferably by means of a mathematical function that can be derived from a calibration of the sensor.

Preferably, the sensor calibration is carried out each time before the actual measurement operation begins. To do this, the sensor can include an additional winding, for example, as a calibration winding.

A “clearance” is understood to mean a free cross-section that is formed in the interior of the magnetic-field-sensitive component.

Preferably, the thickness of the magnetic-field-sensitive component is essentially constant or constant.

The cross-section of the magnetic-field-sensitive component is ring-shaped. The ring may be designed as a circular ring, an oval ring or any other cross-section.

A “turn” is one revolution of a winding around the magnetic-field-sensitive component.

A power supply “conductor” is understood to mean an electrical conductor that has mobile charge carriers and is thus capable of transporting electrical charge. An electrical conductor is preferably understood to mean a copper and/or aluminum cable. In particular, the power supply conductors carry load currents in the power supply network. In the case of a single-phase supply, the power supply conductors can comprise a phase and a neutral conductor, and in the case of a three-phase network, for example, three phases, possibly also with a neutral conductor. Preferably, only those conductors that carry an electrical current in the monitored power supply network during normal operation are routed through the clearance opening as power supply conductors. This applies to the phase(s) and, if applicable, the neutral conductor. In particular, it is suggested that, with the sensor proposed here, no protective conductors should be routed through the clearance opening.

A “limit current” is understood to mean a residual current that a sensor with a control circuit can detect with sufficient accuracy and speed so that the switching device can interrupt the at least two power supply conductors monitored by the sensor as soon as the sensor detects a residual current that reaches or exceeds the limit current.

The smaller the limit current and thus the sensor's suitability for measuring low residual currents and the faster it is reliably detected, the lower the risk that can arise from an occurring residual current.

Preferably, it is suggested that the clearance of the magnetic-field-sensitive component in cross-section exhibits a circle or an ellipse.

Preferably, the magnetic-field-sensitive component features a permeability such that upon reaching saturation, the magnetization curve has as horizontal a course as possible. The more horizontal the curve in the saturation range, the higher the achievable measurement accuracy of the sensor.

It is preferably suggested that the sensor determine the residual current according to the operating principle of a Förster probe.

It is preferable for the turns of the at least one excitation and sensor winding to be distributed equidistantly over the entire circumference of the magnetic-field-sensitive component.

When the at least one excitation and sensor winding is energized by the control circuit, a magnetic flux density that is as locally homogeneous as possible can thus be set up in the magnetic-field-sensitive component.

According to a preferred embodiment of the invention,
the sensor has a sensor shielding with a receptacle in which the magnetic-field-sensitive component having the at least one excitation and sensor winding is housed.

The term “Sensor shielding” refers to a component that is designed to shield electric and/or magnetic fields from the magnetic-field-sensitive component and/or to protect the area around the sensor from the electric and/or magnetic fields emitted by the sensor. In this way, the sensitivity of the sensor for detecting residual currents in the at least two power supply conductors can be improved, since the electric and/or magnetic fields in the magnetic-field-sensitive component are not influenced by external fields, that is, fields from outside the sensor shielding. The electric and/or magnetic fields in the magnetic-field-sensitive component can thus be formed by the residual currents in the power supply conductors, so that the control circuit can detect the occurrence of residual currents with a high degree of accuracy in the resulting sensor signal. A “receptacle” is understood to be the space that is formed inside the shield by the shield and that is designed to receive further components, in particular the magnetic-field-sensitive component and the at least one excitation and sensor winding.

According to a preferred embodiment of the invention,
the switching device has a switching device shielding that provides shielding for the switching device, in particular shielding for a drive coil of the switching device.

The term “switching device shielding” refers to a component that is designed to keep electric and/or magnetic fields away from the switching device and/or to protect the area around the switching device from the electric and/or magnetic fields emitted by the switching device. This is especially beneficial in cases where the switching device comprises an electromechanical drive with a drive coil, as it is easy to generate electric and/or magnetic fields with a drive coil of this kind that can influence the fields in the magnetic-field-sensitive component. Accordingly, the switching device shielding can improve the sensitivity of the sensor for detecting residual currents in the at least two power supply conductors, because the electric and/or magnetic fields in the magnetic-field-sensitive component can be shielded immediately upon their generation. The electric and/or magnetic fields in the magnetic-field-sensitive component can thereby be generated by the residual currents in the power supply conductors without interference from the switching device or from the fields generated by it. Preferably, the switching device shielding is designed and arranged to surround the switching device, in particular its drive coil(s), as directly as possible.

According to a preferred embodiment of the invention,
the residual current device has a shielding device that provides shielding between the switching device and the sensor, in particular shielding between a drive coil of the switching device and the sensor.

The term “Shielding device” refers to a component configured to provide shielding from electric and/or magnetic fields. This particularly concerns the shielding of fields in the magnetic-field-sensitive component so that the electric and/or magnetic fields can build up in the magnetic-field-sensitive component due to the residual currents in the power supply conductors without being influenced by other electric and/or magnetic fields. Accordingly, the shielding device can improve the sensor's sensitivity for detecting residual currents in the at least two power supply conductors.

While the sensor shielding is provided directly on the sensor and the switching device shielding is provided directly on the switching device, the shielding device can be configured to provide efficient shielding independently thereof.

A “shielding”, i.e. the sensor shielding, the switching device shielding or the shielding device, is a component that is configured to shield electrical and/or magnetic fields. In particular, the shielding is intended to prevent the magnetic-field-sensitive component from being influenced by fields that do not originate from a residual current between the at least two power supply conductors. Accordingly, the shielding can be established for the residual current device with only the sensor shielding, the switching device shielding or the shielding device. Alternatively, the shielding can be established by a combination of the sensor shielding and/or the switching device shielding and/or the shielding device.

In summary, the integrated design of the residual current device is an efficient way to ensure that the electrical and/or magnetic fields in the magnetic-field-sensitive component can build up through the residual currents in the power supply conductors without interference from other electrical and/or magnetic fields.

Herein, the shielding as a whole, for example, can be configured and matched to the design of the residual current device in such a way that oversizing of the shielding, i.e. the sensor shielding, the switching device shielding and/or the shielding device, can be avoided.

As an example, the required shielding can be affected by favorable positioning of the switching device, the sensor and the control circuit, in particular by favorable positioning of the switching device and the sensor. The integral design of the switching device, the sensor and the control circuit can thus be adapted to the shielding requirement. Standard shielding is typically somewhat over-dimensioned compared to the adapted shielding proposed here, because it also has to function under worst case conditions. Consequently, shielding material can be saved here, thus reducing costs.

Preferably, each shield may individually comprise an alloy having greater than or equal to 20 weight-% nickel, preferably greater than or equal to 30 weight-% nickel, and more preferably greater than or equal to 50 weight-% nickel. More preferably, each shield may comprise an alloy having greater than or equal to 60 weight-% nickel, more preferably greater than or equal to 70 weight-% nickel, and more preferably greater than or equal to 80 weight-% nickel.

Preferably, each shield may individually comprise an alloy which has a molybdenum content greater than or equal to 0.5 weight-%, preferably greater than or equal to 1 weight-% molybdenum, and more preferably greater than or equal to 3 weight-% molybdenum. Furthermore, the respective shield may preferably comprise an alloy which comprises greater than or equal to 4 weight-% molybdenum, more preferably greater than or equal to 5 weight-% molybdenum and particularly preferably greater than or equal to 5.5 weight-% molybdenum.

Preferably, each shield may individually comprise an alloy comprising greater than or equal to 10 weight-% iron, preferably greater than or equal to 20 weight-% iron, and more preferably greater than or equal to 30 weight-% iron. Further preferably, the respective shield may comprise an alloy having greater than or equal to 40 weight-% iron, further preferably greater than or equal to 50 weight-% iron, and most preferably greater than or equal to 55 weight-% iron.

Shielding can be configured as a coating on an electrically insulating carrier in any case. Alternatively, a coating of an electrically non-conductive material can be applied to the shielding.

This is advantageous for insulating the shielding from electrically conductive components of the residual current device, for example a printed circuit board, so that a short circuit with the shielding can be prevented.

Preferably, the shielding is deep-drawn or injection molded. This can advantageously achieve a cost saving compared to a greater material thickness of the shielding.

When the sensor is operated as designed, the magnetic-field-sensitive component exhibits an oscillating magnetic flux density. Since the shielding is also made of a material with good electrical conductivity, it is subject to an induction effect due to the change in the magnetic flux density of the magnetic-field-sensitive component. Such induction effects are unfavorable because they cause eddy current losses. The eddy current losses that occur during designated operation of the sensor can be reduced by reducing the material thickness of the shielding.

Furthermore, the energy requirement of the sensor can be reduced and the measurement accuracy of the sensor increased.

According to a preferred embodiment of the invention,
the residual current device comprises a charging control circuit, in particular for controlling the charging of an electric vehicle via the at least two power supply conductors of the power supply network, wherein the charging control circuit is preferably designed with the control circuit on a common printed circuit board.

Consequently, the charging control circuit can be used to perform additional tasks in the residual current device over and above controlling the switching mechanism. This means that the residual current device can, for example, take over the function of an in-cable monitoring box. The charge control circuit can be configured to perform safety and communication functions for charging electrically driveable vehicles, for example at household sockets, in order to avoid overloading them. This relates, for example, to a limitation of a continuous current that can be drawn from household sockets. In communication with the electrically driveable vehicle, the supply can be adapted to carry out the charging efficiently and, if possible, without harming the batteries of the electrically driveable vehicle. To do this, for example, signal lines can be provided in the charging cable, the connecting plug and/or the charging plug for communication with the electrically driveable vehicle. As an alternative, wireless communication can be realized.

According to a preferred embodiment of the invention,
the magnetic-field-sensitive component made of a soft magnetic material has a high permeability, which is preferably greater than or equal to 35,000 H/m (Henry per meter), more preferably greater than or equal to 45,000 H/m, more preferred greater than or equal to 60,000 H/m, even more preferred greater than or equal to 100,000 H/m and most particularly preferred greater than or equal to 150,000 H/m, when exposed to a magnetic field oscillating at 50 Hz.

The “permeability” of a magnetic-field-sensitive component is understood to mean the magnetization of a material in an external magnetic field. Higher permeability of the magnetic-field-sensitive component results in a greater ratio of magnetic flux density in the magnetic-field-sensitive component to magnetic field strength acting on the magnetic-field-sensitive component. This means that the magnetic-field-sensitive component with a high permeability results in a comparatively high magnetic flux density in the magnetic-field-sensitive component, even at a low magnetic field strength. Thus, a high permeability of the magnetic-field-sensitive component increases the sensitivity of the sensor and supports the detection of even small residual currents with the sensor.

According to a preferred embodiment of the invention,
the magnetic-field-sensitive component made of a soft magnetic material has a coercive field strength of less than or equal to 10 A/m, preferably less than or equal to 5 A/m, particularly preferably less than or equal to 3 A/m, even more preferably less than or equal to 1 A/m, even more preferably less than or equal to 0.5 A/m and most preferably less than or equal to 0.1 A/m when exposed a magnetic field oscillating at 50 Hz.

As a result of the low coercive field strength of the magnet-sensitive component, a particularly high measurement accuracy can be achieved, particularly with changing field strengths of the magnetic field. The lower the coercive field strength of the magnet-sensitive component, the higher the measurement accuracy with the sensor.

According to a preferred embodiment of the invention,
the soft magnetic material of the magnetic-field-sensitive component comprises an amorphous metal, in particular with a nanocrystalline structure, wherein the amorphous metal is in particular an alloy containing iron, nickel and cobalt.

Preferably, the magnetic-field-sensitive component is made of a nanocrystalline soft magnetic material with a typical grain size in the range of 5 to 30 nm, preferably of a nanocrystalline soft magnetic material with a typical grain size in the range of 7 to 20 nm, particularly preferably of a nanocrystalline soft magnetic material with a typical grain size in the range of 8 to 15 nm.

Preferably, the magnetic-field-sensitive component consists of an alloy which has an iron content of greater than or equal to 70 weight-%, preferably greater than or equal to 71.5 weight-%, and more preferably greater than or equal to 73 weight-%. Preferably, the magnetic-field-sensitive component consists of an alloy which has an iron content of greater than or equal to 73.5 weight-%.

Preferably, the magnetic-field-sensitive component consists of an alloy which has a copper content in the range from 0.75 to 1.25 weight-%, preferably a copper content in the range from 0.85 to 1.15 weight-%, particularly preferably a copper content in the range from 0.95 to 1.05 weight-%. Preferably, the alloy of the magnetic-field-sensitive component has a copper content of 1 weight-%.

Preferably, the magnetic-field-sensitive component consists of an alloy which contains niobium in a range from 2 to 4 weight-%, preferably niobium in a range from 2.5 to 3.5 weight-%, particularly preferably niobium in a range from 2.8 to 3.2 weight-%. Preferably, the magnetic-field-sensitive component's alloy contains at least 3 weight-% niobium.

Preferably, the magnetic-field-sensitive component consists of an alloy that contains boron in a range from 5 to 9 weight-%, preferably boron in a range from 6 to 8 weight-%, particularly preferably boron in a range from 6.5 to 7.5 weight-%. Preferably, the magnetic-field-sensitive component's alloy has a boron content of 7 weight-%.

Preferably, the magnetic-field-sensitive component consists of an alloy which has silicon in a range from 14 to 17 weight-%, preferably silicon in a range from 15 to 16 weight-%, particularly preferably silicon in a range from 15.4 to 15.6 weight-%. Preferably, the alloy of the magnetic-field-sensitive component has a silicon content of 15.5 weight-%.

Preferably, the magnetic-field-sensitive component is made of a particularly thin strip, since in this way, according to Maxwell's equations, the eddy current losses in the magnetically sensitive component can be minimized. The strip is preferably wound in the circumferential direction around the clearance. Preferably, the magnetic-field-sensitive component has a strip thickness in a range between 5 and 50 μm. More preferably, the strip thickness of the magnetic-field-sensitive component is in a range between 7.5 and 40 μm and particularly preferably in a range between 10 and 30 μm.

Preferably, the magnetic-field-sensitive component exhibits a height between 3 and 7 mm, preferably the magnetic-field-sensitive component exhibits a height between 3.4 and 6.6 mm, and particularly preferably the magnetic-field-sensitive component exhibits a height between 3.8 and 6.2 mm. The height of the magnetic-field-sensitive component refers to the extent of the magnetic-field-sensitive component from the clearance opening to the outside. In the case of a magnetic-field-sensitive component with a circular clearance opening, the height of the magnetic-field-sensitive component refers to the extent of the magnetic-field-sensitive component from the clearance opening radially outwards.

According to a preferred embodiment of the invention,
the switching device, the sensor and the control circuit are arranged in a common housing.

By arranging the components in a common housing, it is particularly easy to provide the residual current device in an integrated manner. In practice, the entire residual current device can, for example, be accommodated in a housing of the switching device. The housing can make the residual current device easy to handle and/or install. In addition, the housing can be used, by way of example, as a base for attaching the shield, in particular the shielding device.

According to a preferred embodiment of the invention,
the residual current device comprises at least one current transformer that measures a current through one of the power supply conductors.

Using the at least one current transformer, a current can be detected through the corresponding power supply conductor in order to detect a total current on the respective power supply conductor in addition to the residual current. With two power supply conductors, a total current can be determined via the power supply network, for example to determine the total electrical energy transferred. If there are several power supply conductors, a corresponding number of current transformers must be provided to determine the total electrical energy transferred. The information about the total electrical energy transferred can be used for billing purposes, for example. The current transformer can be a conventional current transformer, for example with a shunt or with a current transformer. The option of determining the total electrical energy transmitted on the supply conductors makes it possible to provide the residual current device as a functional unit in a particularly simple manner. It is no longer necessary to route the power supply conductors over a printed circuit board with appropriately wide conductor tracks that are capable of carrying currents via the power supply conductors, which is common in the prior art, whereby the control circuit can be designed to be simple.

According to a preferred embodiment of the invention, the residual current device comprises a communication interface for communicating with a counterpart on the supply network side, such as a charging device. To do this, for example, signal lines can be provided in the charging cable, the connecting plug and/or the charging plug for the communication connection of the communication interface, for example, with the charging device. Alternatively, the communication interface can be wireless. The communication interface is preferably provided by the control circuit. Alternatively or additionally, the communication interface can be provided by the charging control circuit. Accordingly, information regarding a DC power supply, an AC power supply, an earth (GND), a configuration of the residual current device, in particular of the control circuit, a selection of a tripping characteristic for detecting the residual current and/or carrying out a switching operation with the switching, a detected residual current between the at least two power supply conductors, an AC component and/or a DC component of the residual current, a test input and error messages or error handling can be exchanged between the residual current device and the power supply network-side counterpart. Also, in a configuration of the residual current device with at least one current transformer that detects a current through one of the power supply conductors, a transmitted electrical energy can be communicated to the counterpart on the supply network side via the communication interface. Depending on the type of information transmitted, communication can take place in either direction, including bidirectionally.

The above values for the various compositions and dimensions should not be understood as sharp boundaries, but rather should be exceeded or fallen short of on an engineering scale without leaving the aspect of the invention described. In simple words, the values should provide a guide to the size of the various compositions and dimensions proposed here.

Further advantages, details and features of the invention will become apparent from the following discussion of the various embodiments. In the following is presented:

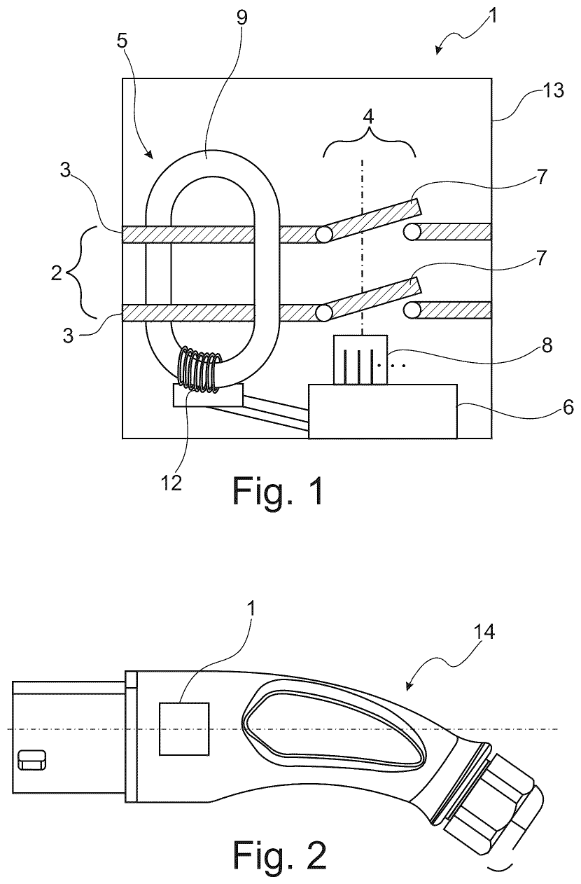

FIG. 1: a schematic illustration of a residual current device according to the invention, according to a first, preferred embodiment of the present invention;

FIG. 2: a schematic illustration of a charging plug for connecting to a charging connection of an electrically drivable vehicle with a residual current device as shown in FIG. 1 according to a second embodiment of the present invention;

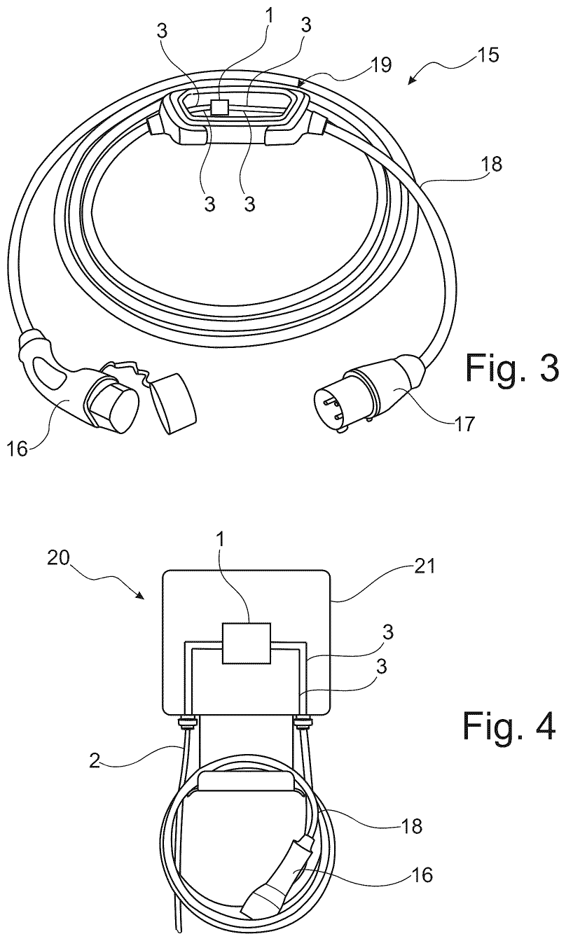

FIG. 3: a schematic illustration of a charging cable with a charging plug for connecting to a charging connection of an electrically drivable vehicle and a connecting plug for connecting to a grid connection of a power supply network, which are connected to one another via an electrical line, and an in-cable monitoring box, which is incorporated into the electrical line and comprises a residual current device as shown in FIG. 1, according to a third embodiment of the present invention;

FIG. 4: a schematic illustration of a charging device for charging an energy storage device of an electrically drivable vehicle with a charging plug for connection to a charging connection of an electrically drivable vehicle, wherein the charging device comprises a residual current device as shown in FIG. 1, according to a fourth embodiment of the present invention;

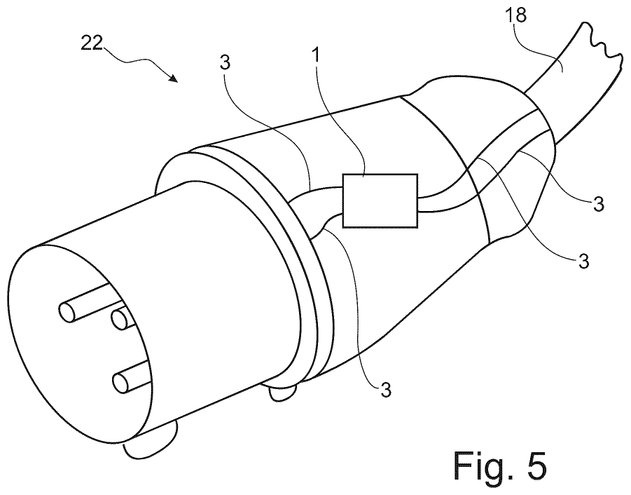

FIG. 5: a schematic illustration of a connecting plug for connecting to a grid connection of a power supply network with a residual current device as shown in FIG. 1, according to a fifth embodiment of the invention; and

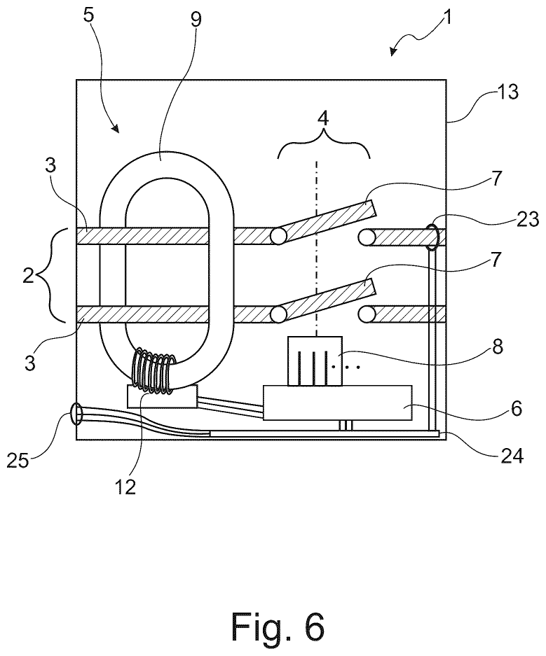

FIG. 6: a schematic representation of a residual current device according to a sixth embodiment of the present invention.

In the following description, the same reference signs denote the same components or the same features, so that a description made in relation to a figure applies to a component in the other figures as well, thus avoiding a repetitive description. Furthermore, individual features described in connection with one embodiment can also be used separately in other embodiments.

FIG. 1 illustrates a residual current device 1 according to a first, preferred embodiment of the present invention.

In this example, the residual current device 1 is configured for connection to a power supply network 2 with two power supply conductors 3. In the case of the single-phase supply shown, the two power supply conductors 3 are configured as a phase and a neutral conductor. For example, the power supply network 2 may include additional protective earth conductors, which are not shown in the figures, for example an additional ground conductor and/or PE (protected earth), being routed in parallel to the power supply conductors 3.

The residual current device 1 includes a switching device 4, which in the present case is configured as a disconnector for interrupting the power supply conductors 3. The residual current device 1 also includes a sensor 5 for detecting residual currents in the power supply conductors 3. The residual current device 1 also includes a control circuit 6 that detects a residual current between the power supply conductors 3 using the sensor 5 and, upon detection of a residual current, triggers the switching device 4 to carry out a switching operation.

The switching device 4 is configured as a relay or also as a contactor. The switching device 4 comprises a mechanical switch 7 for each of the power supply conductors 3, which are operated together by means of an electromechanical drive 8 with a drive coil that is not explicitly shown.

The sensor 5 comprises a magnetic-field-sensitive component 9 with a clearance 10 through which the two power supply conductors 3 are routed. However, additional ground conductors and/or PE (protected earth), which are routed in parallel to the power supply conductors 3, are not routed through the clearance 10. The clearance 10 of the magnetic-field-sensitive component 9 has a circular cross-section. The magnetic-field-sensitive component 9 has a circular ring shape in cross-section. The material thickness of the magnetic-field-sensitive component 9 is essentially constant or constant over the entire circumference.

In addition, the sensor 5 comprises at least one excitation and sensor winding 12, which respectively enclose the magnetic-field-sensitive component 9 with a plurality of turns. In this embodiment, the turns of the at least one excitation and sensor winding 12 are distributed equidistantly over the entire circumference of the magnetic-field-sensitive component 9, with the at least one excitation and sensor winding 12 being shown in FIG. 1 as an example for only part of the magnetic-field-sensitive component 9.

The magnetic-field-sensitive component 9 has a soft magnetic material with a high permeability, which is greater than or equal to 100,000 H/m in the case of a magnetic field oscillating at 50 Hz. In addition, the magnetic-field-sensitive component 9 has a low coercive field strength, which is less than or equal to 1 A/m in a magnetic field oscillating at 50 Hz. Alternatively or additionally, the magnetic-field-sensitive component 9 has a magnetic saturation flux density greater than or equal to 1.3 T.

Furthermore, the magnetic-field-sensitive component 9 has a permeability such that when saturation is reached, the magnetization curve is essentially horizontal.

The soft magnetic material of the magnetic-field-sensitive component 9 is an amorphous metal with a nanocrystalline structure, the amorphous metal being an alloy containing iron, nickel and cobalt.

The magnetic-field-sensitive component 9 is made of a strip with a low strip thickness. The strip is wound in the circumferential direction around the clearance 10 and has a strip thickness in a range between 5 and 50 μm. The strip is wound so that the magnetic-field-sensitive component 9 has a height between 3 and 7 mm.

The control circuit 6 is configured to control the sensor 5 and to detect AC and/or DC components of the residual current in the power supply conductors 3 by means of the at least one excitation and sensor winding 12. The control circuit 6 determines the residual current using the sensor 5 according to the operating principle of a Förster probe.

The at least one excitation and sensor winding 12 is thus actively supplied with an electric current by the control circuit 6 by means of a current source, whereby an electromagnetic field is generated or influenced in the magnetic-field-sensitive component 9. Alternatively, the at least one excitation and sensor winding 12 can also be connected to a voltage source.

In the at least one excitation and sensor winding 12, an electric current is induced as a result of an induction effect that originates from the magnetic-field-sensitive component 9. This induced current alters the total current through the at least one excitation and sensor winding 12, thereby providing a sensor winding signal that represents a sensor signal. If there is a residual current between the at least two power supply conductors 3, the total current is altered. If there is no residual current between the power supply conductors 3, the induced currents through the power supply conductors 3 essentially cancel each other out and the total current is unchanged.

In order to shield the magnetic-field-sensitive component 9 having the at least one excitation and sensor winding 12, the sensor 5 has a sensor shielding with a receptacle in which the magnetic-field-sensitive component 9 having the at least one excitation and sensor winding 12 is received.

Furthermore, the switching device 4 has a switching device shielding which has the effect of shielding the switching device 4, in particular a shielding of a drive coil of the switching device 4.

Also, the residual current device 1 is designed with a shielding device that provides shielding between the switching device 4 and the sensor 5.

By means of the sensor shielding, the switching device shielding and the shielding device, which are not shown in FIG. 1, electrical and/or magnetic fields are shielded respectively, so that the electrical and/or magnetic fields are formed in the magnetic-field-sensitive component 9 by the residual currents in the power supply conductors 3 without being influenced by external electrical and/or magnetic fields. The shielding with the sensor shielding, the switching device shielding and the shielding device as a whole is designed and adapted to the design of the residual current device 1 in such a way that over-dimensioning of the shielding is avoided. This includes favorable placement of the switching device 4, the sensor 5 and the control circuit 6.

The shielding may in any case be designed as a coating on an electrically insulating carrier. Alternatively, a coating of an electrically non-conductive material may be applied to the shielding.

The switching device 4, the sensor 5 and the control circuit 6 are integrally designed in this embodiment and arranged in a common housing 13. In one embodiment, the common housing 13 is a housing 13 of the switching device 4, in which the sensor 5 and the control circuit 6 are additionally received.

FIG. 2 illustrates a charging plug 14 according to a second embodiment. The charging plug 14 has a residual current device 1.

The charging plug 14 in this embodiment is used to connect the two power supply conductors 3 of the power supply network 2 to a charging connection of an electrically drivable vehicle. In addition, the charging plug 14 can, for example, connect additional protective conductors that are routed parallel to the power supply conductors 3 in the charging plug 14.

In this embodiment, the charging plug 14 is a Type 2 charging plug, predefined in terms of its function and contacts, as can also be seen in FIG. 2. The Type 2 charging plug is also known as the Mennekes plug.

FIG. 3 illustrates a charging cable 15 according to a third embodiment. The charging cable 15 comprises a charging plug 16 for connection to a charging connection of an electrically drivable vehicle. In this embodiment, the charging plug 16 is designed without a residual current device 1. The charging plug 16 of the third embodiment is also a Type 2 charging plug 16.

The charging cable 15 also comprises a connecting plug 17 for connection to a grid connection of the power supply network 2 with the two power supply conductors 3.

The charging plug 16 and the connecting plug 17 are connected to each other via an electrical line 18 with two power supply conductors 3. An in-cable monitoring box 19 is incorporated into the electrical line 18.

The in-cable monitoring box 19 in this embodiment comprises a residual current device 1 as shown in FIG. 1. The residual current device 1 comprises in detail additional functions for controlling the charging of the connected electrically drivable vehicle. Consequently, the control circuit 6 is configured to perform charging control via the two power supply conductors 3 of the power supply network 2. The control circuit 6 is configured to perform safety and communication functions for charging the electrically drivable vehicle, for example, at household sockets. This relates to e.g. a limitation of a continuous current that can be drawn from the household sockets. Furthermore, the control circuit 6 is configured to communicate with the electrically drivable vehicle, for example via the power supply conductors or additional data lines formed in the electrical line 18, to carry out the charging efficiently and preferably without damaging the batteries of the electrically driveable vehicle.

FIG. 4 illustrates a charging device 20 according to a fourth embodiment. The charging device 20 is configured to charge an energy storage device of an electrically drivable vehicle via two power supply conductors 3 of a power supply network 2.

As illustrated in FIG. 4, the charging device 20 has a residual current device 1 depicted in FIG. 1. The charging device 20 is designed as a wall charging station for wall mounting. The charging device 20 comprises a station housing 21. An electrical line 18 is permanently connected to the charging device 20, the electrical line 18 having two power supply conductors 3 in this exemplary implementation.

A charging plug 16 is attached to the free end of the electrical line for connecting to the electrically drivable vehicle. The charging plug 16 of the fourth embodiment is also a Type 2 charging plug 16. Since the residual current device 1 is integrated in the charging device 20, no in-cable monitoring box 19 is provided along the electrical line 18, nor is a residual current device 1 provided in the charging plug 16.

FIG. 5 illustrates a connecting plug 22 according to a fifth embodiment. The connecting plug 22 comprises a residual current device 1.

The connecting plug 22 is used in this embodiment to connect the two power supply conductors 3 to a grid connection of the power supply network 2, in particular to connect a charging cable 15 for an electrically drivable vehicle to the grid connection of the power supply network 2. In addition, the connecting plug 22 can, for example, connect additional protective conductors that are routed in parallel to the power supply conductors 3 in the connecting plug 22.

The connecting plug 22 is a standardized connecting plug 22 that is predefined in terms of its function and contacts. Various connecting plugs 22 are known as such and can be used.

FIG. 6 illustrates a residual current device 1 according to a sixth embodiment of the present invention.

The residual current device 1 of the sixth embodiment is based on the residual current device 1 of the first embodiment, so that in the further description, essentially only the differences between the residual current device 1 of the sixth embodiment and the residual current device 1 of the first embodiment will be described in detail. Features that are not discussed in detail correspond, where necessary, to those of residual current device 1 of the first embodiment.

The residual current device 1 of the sixth embodiment is also designed for connection in a power supply network 2 with two power supply conductors 3. It also includes a switching device 4, a sensor 5 for detecting residual currents in the power supply conductors 3 and a control circuit 6 which, using the sensor 5, detects a residual current between the power supply conductors 3 and, when a residual current is detected, triggers the switching device 4 to carry out a switching operation.

The residual current device 1 of the sixth embodiment also has a shielding which, as previously described, may comprise a sensor shielding, a switching device shielding and/or a shielding device.

In contrast to the residual current device 1 of the first embodiment, the residual current device 1 of the sixth embodiment additionally has a current transformer 23 that detects a current through one of the power supply conductors 3. The current transformer 23 detects a current through the corresponding power supply conductor 3. This makes it possible to detect, in addition to the residual current through the two power supply conductors 3, a total current on the respective power supply conductor 3, from which a total transmitted electrical energy can be determined. In this embodiment, the current transformer 23 is a conventional current transformer 23 with a current transformer.

Contrary to the residual current device 1 of the first embodiment, the residual current device 1 of the sixth embodiment additionally comprises a charging control circuit 24 for controlling the charging of an electric vehicle via the two power supply conductors 3 of the power supply network 2. In this embodiment, the charging control circuit 24 is designed separately from the control circuit 6 and is connected to it, in particular for communication. In an alternative embodiment, the charging control circuit 24 and the control circuit 6 are implemented on a common printed circuit board. The charging control circuit 24 performs additional tasks to the tasks of the control circuit 6. In this embodiment, these are functions that are usually provided by an in-cable monitoring box. Accordingly, the charging control circuit 24 carries out safety and communication functions for charging electrically driveable vehicles, for example, at household sockets, for example, a limitation of a continuous current that can be drawn from the household sockets. In communication with the electrically driveable vehicle, the supply is adapted in order to carry out the charging efficiently and, if possible, without damage to the batteries of the electrically driveable vehicle.

In this embodiment, the charging control circuit 24 is integrally designed with a control for the current transformer 23 and is connected thereto.

In contrast to the residual current device 1 of the first embodiment, the residual current device 1 of the sixth embodiment additionally comprises a communication interface 25 for communicating with a counterpart on the supply network side, for example with a charging device 20. To this end, for example, signal lines can be provided in the charging cable 15, the connecting plug 17, 22 and/or the charging plug 14, 16 for the communication connection of the communication interface 25.

The communication interface 25 is provided in this embodiment by the charge control circuit 24. The charge control circuit 24 communicates internally with the control circuit 6 as required. In an alternative embodiment, the communication interface 25 is provided by the control circuit 6, which communicates internally with the charge control circuit 24 as required.

The residual current device 1 communicates with the counterpart on the supply network side via the communication interface 25 and exchanges information, for example, about a DC power supply, an AC power supply, an earth (GND), a configuration of the residual current device 1, in particular of the control circuit 6, a selection of a tripping characteristic for detecting the residual current and/or carrying out a switching operation with the switching device 4, a detected residual current between the power supply conductors 3, an AC component and/or a DC component of the residual current, a test input and error messages or error handling. In addition, the electrical energy transferred is transmitted to the supply network-side counterpart via the communication interface. In total, information from the residual current device 1 can be transmitted to the supply network-side counterpart. In addition, information from the supply network-side counterpart can be transmitted to the residual current device 1.

Furthermore, a configuration can be performed between the residual current device 1 and the power supply-side counterpart.

In a corresponding manner, the residual current device 1 may comprise a communication interface, not shown here, for communication with the electrically drivable vehicle connected in each case. For this purpose, for example, signal lines can be provided in the charging cable 15, the connecting plug 17, 22 and/or the charging plug 14, 16 for the communication connection of the communication interface.

As an alternative, wireless communication instead of the communication interface 25 as well as the communication interface can be provided.

The switching device 4, the sensor 5, the control circuit 6, the current transformer 23 and the charging control 24 with the communication interface 25 are integrally embodied in the sixth embodiment and arranged in a common housing 13. In one embodiment, the common housing 13 is a housing 13 of the switching device 4, in which the sensor 5, the control circuit 6, the current transformer 23 and the charging control 24 with the communication interface 25 are additionally received.

### LIST OF REFERENCES

1 Residual current device
2 Power supply network
3 Power supply conductor
4 Switching device
5 Sensor
6 Control circuit
7 Switch
8 Electromechanical drive
9 Magnetic-field-sensitive component
10 Clearance
12 Excitation and sensor winding
13 Housing
14 Charging plug (with residual current device)
15 Charging cable
16 Charging plug (without residual current device)
17 Connecting plug (without residual current device)
18 Electrical line
19 In-cable monitoring box
20 Charging device
21 Station housing
22 Connecting plug (with residual current device)
23 Current transformer
24 Charge control circuit
25 Communication interface

1. A residual current device for connection in a power supply network including at least two power supply conductors, comprising:
a switching device for interrupting the at least two power supply conductors,
a sensor for detecting residual currents in the at least two power supply conductors, and
a control circuit which is designed to detect a residual current between the at least two power supply conductors using the sensor and, when a residual current is detected, to control the switching device to carry out a switching operation,
wherein:
the sensor comprises a magnetic-field-sensitive component including a clearance through which the at least two power supply conductors are routed, and at least one excitation and sensor winding which, with a plurality of turns, encloses the magnetic-field-sensitive component,
the magnetic-field-sensitive component is made of a soft magnetic material,
the control circuit is designed to control the sensor and to detect AC and/or DC components of the residual current in the at least two power supply conductors via the at least one excitation and sensor winding, and
the switching device, the sensor and the control circuit are designed integrally.

2. The residual current device according to claim 1, wherein:
the sensor includes a sensor shielding with a receptacle in which the magnetic-field-sensitive component including the at least one excitation and sensor winding is housed.

3. The residual current device according to claim 1, wherein:
the switching device has a switching device shielding that provides shielding for the switching device.

4. The residual current device according to claim 1, wherein:
the residual current device includes a shielding device that provides shielding between the switching device and the sensor shielding between a drive coil of the switching device and the sensor.

5. The residual current device according to claim 1, wherein:
the residual current device comprises a charging control circuit for controlling the charging of an electric vehicle via the at least two power supply conductors of the power supply network, wherein the charging control circuit is preferably designed with the control circuit on a common printed circuit board.

6. The residual current device according to claim 1, wherein:
the magnetic-field-sensitive component made of a soft magnetic material has a high permeability, which is greater than or equal to 35,000 H/m (Henry per meter) when exposed to a magnetic field oscillating at 50 Hz.

7. The residual current device according to claim 1, wherein:
the magnetic-field-sensitive component made of a soft magnetic material has a coercive field strength of less than or equal to 10 A/m when exposed a magnetic field oscillating at 50 Hz.

8. The residual current device according to claim 1, wherein:
the soft magnetic material of the magnetic-field-sensitive component comprises an amorphous metal with a nanocrystalline structure, wherein the amorphous metal is an alloy containing iron, nickel and cobalt.

9. The residual current device according to claim 1, wherein:
the switching device, the sensor and the control circuit are arranged in a common housing.

10. The residual current device according to claim 1, wherein:
the residual current device comprises at least one current transformer that measures a current through one of the power supply conductors.

11. The residual current device according to claim 1, wherein:
the residual current device comprises a communication interface for communicating with a counterpart on the supply network side.

12. A charging plug for connecting at least two power supply conductors to a charging connection for connection to a charging connection of an electrically drivable vehicle,
wherein:
the charging plug comprises a residual current device according to claim 1.

13. A connecting plug for connecting at least two power supply conductors to a grid connection of a power supply network for connecting a charging cable for an electrically drivable vehicle to the grid connection of the power supply network,
wherein:
the connecting plug comprises a residual current device according to claim 1.

14. An in-cable monitoring box for insertion into an electrical line including at least two power supply conductors into a charging cable for connecting a charging connection of an electrically drivable vehicle to a grid connection of a power supply network,
wherein:
the in-cable monitoring box comprises a residual current device according to claim 1.

15. A charging cable including a charging plug for connection to a charging connection of an electrically driveable vehicle and a connecting plug for connection to a grid connection of a power supply network, wherein:
the charging plug and the connecting plug are connected to one another via an electrical line including at least two power supply conductors,
wherein:
the charging plug is configured as the charging plug according to claim 12.

16. A charging cable including a charging plug for connection to a charging connection of an electrically driveable vehicle and a connecting plug for connection to a grid connection of a power supply network, wherein:
the charging plug and the connecting plug are connected to each other via an electrical line including at least two power supply conductors,
wherein:
the connecting plug is configured as the connecting plug according to claim 13.

17. A charging cable including a charging plug for connection to a charging connection of an electrically driveable vehicle and a connecting plug for connection to a grid connection of a power supply network, wherein:
the charging plug and the connecting plug are connected to one another via an electrical line including at least two power supply conductors, and
the charging cable comprises an in-cable monitoring box that is integrated into the electrical line,
wherein:
the in-cable monitoring box is configured as the in-cable monitoring box according to claim 14.

18. A charging device for charging an energy storage device of an electrically driveable vehicle via at least two power supply conductors of a power supply network,
wherein:
the charging device comprises a residual current device according to claim 1.
